(19) United States
(12) Patent Application Publication
(10) Pub. No.: US 2024/0006378 A1
(43) Pub. Date: Jan. 4, 2024

(54) MULTIPLE COMPOSITION THERMAL INTERFACE MATERIALS FOR MULTI-DIE PACKAGES

(71) Applicant: Intel Corporation, Santa Clara, CA (US)

(72) Inventors: Sergio Antonio Chan Arguedas, Chandler, AZ (US); Zheng Ren, Chandler, AZ (US); Arifur Chowdhury, Chandler, AZ (US)

(21) Appl. No.: 17/855,145

(22) Filed: Jun. 30, 2022

(51) Int. Cl. H01L 25/065; H01L 25/18; H01L 23/367; H01L 23/00

(52) U.S. Cl. CPC H01L 25/0655; H01L 25/18; H01L 23/3675; H01L 24/83; H01L 24/16; H01L 2224/16225; H01L 24/32; H01L 2224/32245; H05K 1/181

(57) ABSTRACT

A die package comprises a substrate comprising a first face and an opposing second face, a first semiconductor die coupled to the first face of the substrate, a second semiconductor die coupled to the first face of the substrate; and a heat spreader, wherein the first semiconductor die is thermally connected to the heat spreader by a first thermal interface material and the second semiconductor die is thermally connected to the heat spreader by a second thermal interface material, wherein the first thermal interface material comprises a first composition and the second thermal interface material comprises a second composition, wherein the first composition has a lower elastic modulus than the second composition under a first specified condition or conditions.

### TECHNICAL FIELD

Embodiments described herein generally relate to temperature management in electronic devices. More specifically, embodiments described herein relate to improved thermal interface materials for temperature management of multi-die packages in electronic devices.

### BACKGROUND

Semiconductor packages may include more than one semiconductor die coupled to the same substrate. The semiconductor package can also include one or more structures for thermal management of the semiconductor dies or the package as a hole. One example of a thermal-management structure is a heat spreader that conducts heat from a die in the package in order to minimize temperature rise of the die or other structures in the package. Thermal interface materials are often used to ensure physical connection between the heat spreader and the die or other structure from which the heat spreader is intended to draw heat. Maintaining thermal contact between the thermal interface material and the heat spreader or the heated die is important in order to maintain adequate heat flow from the die or other structure.

### BRIEF DESCRIPTION OF THE DRAWINGS

FIG. 1 is a cross-sectional elevation view of a portion of an example electronic device with multiple thermal interface materials for heat management of multiple dies in a multi-die package, in accordance with some example embodiments.

FIGS. 2A-2C are photographs of two thermal interface material structures having the same composition in multi-die packages where the dies have various die height differences.

FIGS. 3A and 3B are photographs of two thermal interface material structures having multiple compositions in multi-die packages where the dies have various die height differences.

FIG. 4 is a flow diagram showing an example method of manufacturing an electronic device that includes multiple thermal interface materials, in accordance with some example embodiments.

FIGS. 5A-5F show cross-sectional side views of various steps of a method of manufacturing a die package with multiple thermal interface materials for heat management of multiple dies, in accordance with some example embodiments.

FIG. 6 is a system diagram depicting a system that may incorporate the example multiple thermal interface materials in a multi-die package, in accordance with some example embodiments.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

The present application, in one or more embodiments, relates to multi-die packages in electronic devices wherein each of the plurality of dies are in thermal contact with a heat spreader by a thermal interface material. As used herein, the phrases “in thermal contact with,” “thermal contact,” or “thermal connection” refers to a die or other structure within a package being in physical contact with a thermal interface material and that same thermal interface material being in physical contact with a heat spreader, i.e., such that heat can conductively flow from the die or other structure to the thermal interface material and then from the thermal interface material to the heat spreader. In some examples, a die or other structure can be considered to be in thermal contact with a heat spreader if that die or other structure is directly in physical contact with the heat spreader (e.g., without the presence of a thermal interface material positioned between the die or other structure and the heat spreader). However, as will be appreciated by those having skill in the art, it may be difficult to guarantee sufficient thermal contact between the die or other structure and the heat spreader after manufacturing tolerances are taken into account.

As used herein, the term “thermal interface material” refers to a material (which can be a single composition material or a mixture or composite comprising two or more different compositions or materials combined together in a single structure) that has a minimum specified thermal conductivity so that a heat flow rate through the thermal interface material will be at or above a specified heat transfer rate. A non-limiting example of a specified minimum thermal conductivity that can be specified for a thermal interface material used in an electronic device of the present disclosure is at least about 4 watts per meter-kelvin (W/m-K). In other non-limiting examples, the thermal interface material can have a thermal conductivity of from about 70 W/m-K to about 80 W/m-K.

It is common for electronic devices to include packages with more than one semiconductor die mounted to the same substrate. In these multi-die packages, the dies can have different sizes so that when they are mounted to the substrate there is a height difference between the dies. Even in embodiments where all of the dies have the same nominal size and are specified to have the same height when mounted to the substrate, manufacturing irregularities can result in the dies having slightly different heights. For example, the dies themselves may end up having slightly different thicknesses or the solder joints that couple one die to the substrate may have a slightly different size than the solder joints that couple another die to the substrate. Manufacturing irregularities can result in die height differences of about 10 micrometers (μm) or more, for example about 15 μm or more, such as about 20 μm or more, such as about 25 μm or more, for example about 30 μm or more, such as about 35 μm or more, for example about 40 μm or more, such as about 45 μm or more, for example about 50 μm or more.

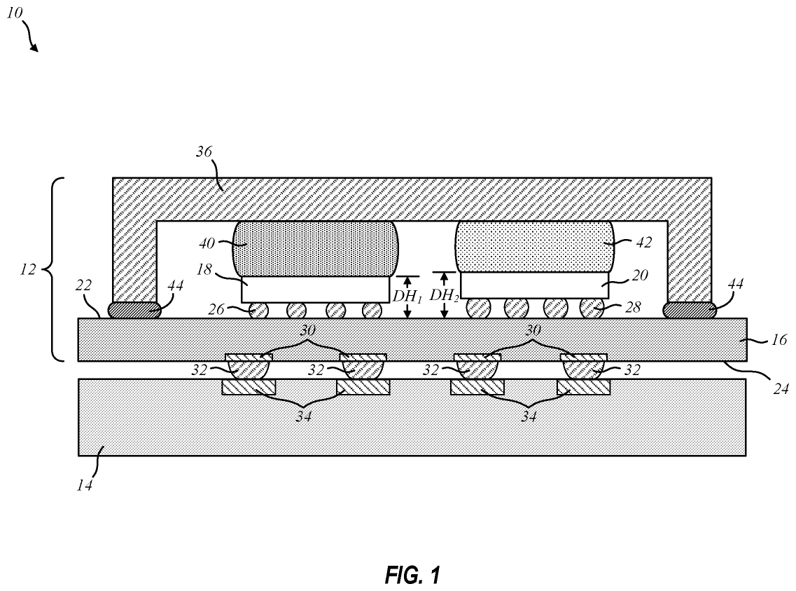

FIG. 1 illustrates an electronic device 10 that provides for a solution for these problems often associated with a multi-die package via the use of multiple compositions of thermal interface materials (TIMs), which can account for height differences to ensure good thermal contact between the semiconductor dies and a heat spreader via the TIMs. The electronic device 10 includes an electronic die package 12 (also referred to “the die package 12” or “the package 12”) that is electrically and mechanically coupled to a circuit board 14, such as a motherboard 14. In an example, the die package 12 comprises a die package substrate 16 (also referred to as “the package substrate 16” or simply as “the substrate 16”) with two or more semiconductor dies 18, 20 coupled to the same face of the substrate 16. In the example of FIG. 1, the electronic package 12 comprises two semiconductor dies, a first semiconductor die 18 and a second semiconductor die 20. Both the first semiconductor die 18 and the second semiconductor die 20 are coupled to a first face 22 of the substrate 16 (e.g., a top face 22 in the orientation shown in FIG. 1). In an example, a second face 24 of the substrate 16 is coupled to the circuit board 14, wherein the second face 24 opposes the first face 22 (e.g., the bottom face 24 in the orientation shown in FIG. 1).

In an example, the first semiconductor die 18 is coupled to the first face 22 of the substrate 16 with a plurality of first solder joints 26 and the second semiconductor die 20 is coupled to the first face 22 of the substrate 16 with a plurality of second solder joints 28. The solder joints 26, 28 can each be coupled to a corresponding contact pad on its corresponding die 18, 20 and on the substrate 16 (not shown in FIG. 1). In an example, each semiconductor die 18, 20 comprises one of any type of microelectronic device including, but not limited to, integrated circuits (ICs), chips, chip sets, memory devices, processors, such as a central processing unit (CPU), a graphics processing unit (GPU), advanced processing unit (APU), or combinations thereof.

The substrate 16 can also include a plurality of land solder pads 30 (also referred to hereinafter as “solder pads 30”) located on the second face 24 of the substrate 16, i.e., opposite to the face of the substrate 16 onto which the semiconductor dies 18, 20 are coupled. For example, as shown in FIG. 1, the one or more dies 18, 20 can be electrically and mechanically coupled to the top face 22 of the substrate 16 and the solder pads 30 are located on the bottom face 24 of the substrate 16 (in the orientation shown in FIG. 1). The solder pads 30 can be electrically connected to the one or more semiconductor dies 18, 20 by one or more internal structures in the substrate 16, such as vias or other known interconnect structures (not shown). A solder joint 32 can be formed onto each of the solder pads 30 for electrically and mechanically connecting each solder pad 30 to a corresponding contact pad 34 on the circuit board 14.

In an example, the package 12 can also include a heat spreader 36 to help manage the temperature of the semiconductor dies 18, 20. As discussed above, the heat spreader 36 is configured to conduct heat away from the semiconductor dies 18, 20 of the package 12. For example, as will be appreciated by those having skill in the art, each semiconductor die 18, 20 can generate a relatively large amount of heat during operation that can eventually damage the dies 18, 20 or other structures of the electronic device 10 if the heat is not dissipated away from the semiconductor dies 18, 20. In an example, the heat spreader 36 comprises one or more materials that have a high thermal conductivity. In an example, the heat spreader 36 comprises a metal structure formed from a metal or other high-conductivity materials, including, but not limited to, silver, copper, aluminum, nickel, or a silver-diamond composite.

As is also described above, the package 12 can include thermal interface materials to ensure a sufficient thermal connection between each semiconductor die 18, 20 and the heat spreader 36. In an example, a first thermal interface material 40 (also referred to herein as “the first TIM 40”) provides for thermal contact between the first semiconductor die 18 and the heat spreader 36 and a second thermal interface material 42 (also referred to herein as “the second TIM 42”) provides for thermal contact between the second semiconductor die 20 and the heat spreader 36. In an example, one or both of the TIMs 40, 42 can comprise any type of composition that is useful as a thermal interface material in an electronic device. Examples of thermal interface materials that could be used as the TIMs 40, 42 include, but are not limited to, a solder-based thermal interface material (also often referred to as “a solder thermal interface material” or “STIM”) or a polymer-based thermal interface material (also often referred to as “a polymer thermal interface material” or “PTIM”). An example of a solder-based thermal interface material that could be used as either the first TIM 40 or the second TIM 42, or both, is a metal alloy comprising indium (In) and one or more other metal elements, such as, but not limited to, an indium-tin (In—Sn) alloy, an indium-silver (In—Ag) alloy, an indium-gold (In—Au) alloy, an indium-nickel (In—Ni) alloy, an indium-tin-silver (In—Sn—Ag) alloy, an indium-tin-bismuth (In—Sn—Bi) alloy, or an indium-silver-nickel (In—Ag—Ni) alloy. An example of a polymer-based thermal interface material that could be used as either the first TIM 40 or the second TIM 42, or both, is a polymer base mater filed with thermally conductive particles, such as aluminum oxide particles, zinc oxide particles, or a polymer matrix that comprises boron nitride or carbon fiber filler particles.

In an example, the heat spreader 36 can be coupled to another structure of the electronic device 10, such as to the package substrate 16 as shown in FIG. 1. The heat spreader 32 can be coupled to the other structure with an adhesive 44. In another example, not shown, the heat spreader 36 can be coupled to the circuit board 14 by the adhesive 44. In an example, the adhesive 40 is thermally conductive so that heat can be conducted from the heat spreader 36 to the other structure, e.g., from the heat spreader 36 to the package substrate 16.

In an example, the first semiconductor die 18 and the second semiconductor die 20 can have different die heights. As used herein, the term “die height” refers to the distance from the surface to which a semiconductor die 18, 20 is coupled (i.e., the first face 22 of the substrate 16 in the example electronic device 10 of FIG. 1) and the outermost surface of the semiconductor die 18, 20 (e.g., a top surface of the semiconductor dies 18, 20 in the orientation shown in FIG. 1). The two semiconductor dies 18, 20 can have different die heights because, for example, the two semiconductor dies 18, 20 are designed to have different heights (e.g., the first semiconductor die 18 is designed to have a different thickness than the second semiconductor die 20). In other examples, the two semiconductor dies 18, 20 can be specified to have the same die height (e.g., the two semiconductor dies 18, 20 can have the same thickness and can be intended to have the same size of solder joints 26, 28), but can end up having different die heights because of manufacturing variance that causes different heights. In the example shown in FIG. 1, the first semiconductor die 18 has the same thickness as the second semiconductor die 20, but due to manufacturing variance, the first solder joints 26 ended up being slightly smaller than the second solder joints 28 so that a first die height DH₁ of the first semiconductor die 18 is slightly shorter than a second die height DH₂ of the second semiconductor die 20.

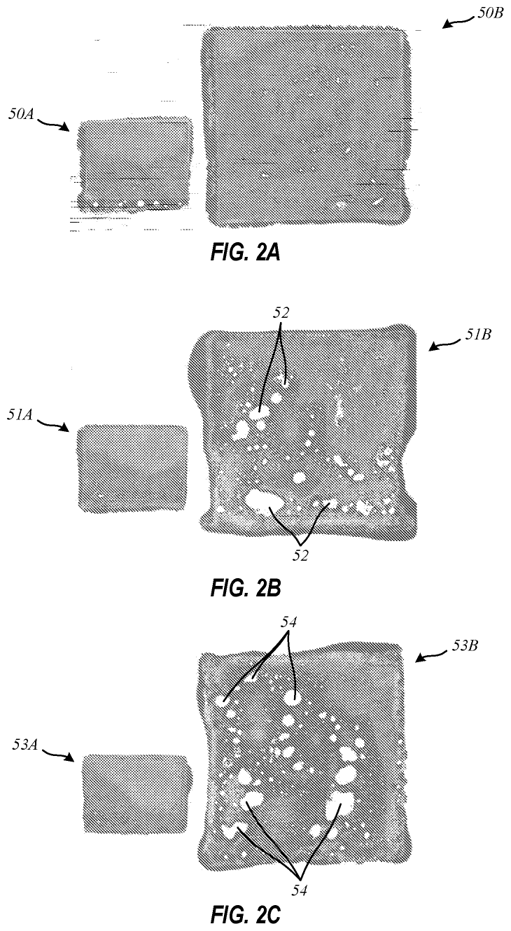

When the two different semiconductor dies 18, 20 have different die heights DH₁, DH₂, it can be difficult to ensure sufficient thermal contact between the heat spreader 36 and the TIMs 40, 42. This is demonstrated by FIGS. 2A-2C, which each show a photograph of two example thermal interface material structures that are intended to provide thermal contact between a pair of semiconductor dies and a heat spreader in the same multi-die package, similar to the TIMs 40, 42 that are intended to provide thermal contact between the semiconductor dies 18, 20 and the heat spreader 36 in the electronic device 10 of FIG. 1. However, unlike the TIMs 40, 42 in the electronic device 10, the two thermal interface material structures in each of FIGS. 2A-2C were made from the same composition material instead of the TIMs 40, 42, which are made from two different compositions (as described in more detail below).

FIG. 2A shows two thermal interface material structures 50A and 50B that had provided thermal contact for two semiconductor dies with the same die height (e.g., wherein DH₁≈DH₂). As can be seen in FIG. 2A, both the first thermal interface material structure and the second thermal interface material structure 50B have relatively few voids, and thus both provide adequate thermal contact with the heat spreader.

FIG. 2B shows an image of two thermal interface material structures 51A and 51B wherein there was a 25 μm difference in die height between the semiconductor dies. Specifically, the first thermal interface material structure 51A was in contact with a semiconductor die with a die height that was 25 μm taller than the die height of the semiconductor die in which the second thermal interface material structure 51B was in contact (e.g., DH₁=DH₂+25 μm). As can be seen in FIG. 2B, the 25 μm difference in die height resulted in the formation of several air pockets or voids 52. As will be appreciated by those having skill in the art, air is a thermal insulator, so the formation of the voids 52 can result in substantially less efficient transfer of heat from the thermal interface material structure 51B and its semiconductor die compared to the first thermal interface material structure 51A and its semiconductor die.

FIG. 2C shows an image of two more thermal interface material structures 53A and 53B for thermally connecting semiconductor dies having differing die heights, specifically a 50 μm difference in die height, for example, with the die height of the semiconductor die that is in contact with the first thermal interface material structure 53A being 50 μm taller than the die height of the semiconductor die in which the second thermal interface material structure 53B was in contact (e.g., DH₁=DH₂+50 μm). As can be seen in FIG. 2C, the 50 μm difference in die height resulted in the formation of even more voids 54 for the second thermal interface material structure 53B then had occurred with the 25 μm die height difference in FIG. 2B, and thus resulted in even poorer thermal contact with the heat spreader and even less efficient heat transfer for the second thermal interface material structure 53B and its corresponding semiconductor die.

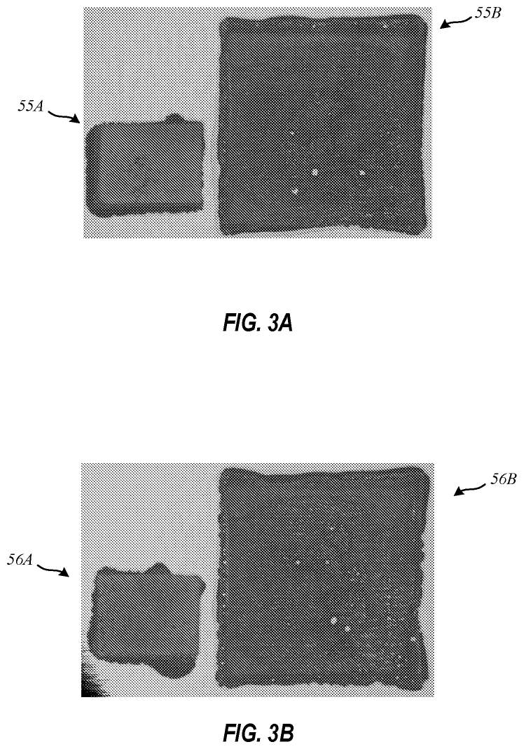

For comparison, FIGS. 3A and 3B show photographs of two examples of the multi-composition thermal interface materials 40, 42 of the present disclosure with two different die height differences, which shows how the multi-composition TIMs 40, 42 of the present disclosure can accommodate varying die height and still provide for good thermal contact. FIG. 3A shows an image of two thermal interface material structures 55A and 55B for thermally connecting semiconductor dies having the same die heights as in the photograph of FIG. 2B, i.e., a 25 μm difference in die height between the semiconductor dies with the first thermal interface material structure 55A being in contact with a semiconductor die with a die height that was 25 μm taller than the die height of the semiconductor die in which the second thermal interface material structure 55B was in contact (e.g., DH₁=DH₂+μm). FIG. 3B shows an image of two more thermal interface material structures 56A and 56B for thermally connecting semiconductor dies having the same die heights as in the photograph of FIG. 2C, i.e., a 50 μm difference in die height between the semiconductor dies with the first thermal interface material structure 56A being in contact with a semiconductor die with a die height that was 50 μm taller than the die height of the semiconductor die in which the second thermal interface material structure 56B was in contact (e.g., DH₁=DH₂+μm). As can be seen by a comparison of FIG. 2B with FIG. 3A and a comparison of FIG. 2C with FIG. 3B, the multi-composition thermal interface material structures 55A, 55B, 56A, 56B is able to accommodate relatively large gaps in die height in the same semiconductor package, and therefore is much more efficient at providing for thermal contact between a heat spreader and all semiconductor dies in the package.

As described in more detail below, the two TIMs 40, 42 have different compositions such that a first composition that is used to form a first one of the TIMs 40, 42 is more deformable under a first specified condition or conditions than a second composition that is used to form the other of the TIMs 40, 42 so that during fabrication of the package 12 when the package 12 is subjected to the first specified condition or conditions, the first one of the TIMs 40, 42 will be deformed to allow the heat spreader 36 to come into contact with the other of the TIMs 40, 42. Then, optionally, the package 12 can be subjected to a second specified condition or conditions, wherein the other of the TIMs 40, 42 is deformable under the second specified condition or conditions to ensure that there is sufficient thermal contact between the heat spreader 36 and both of the TIMs 40, 42, as described in more detail below. FIG. 1 shows both the first TIM 40 and the second TIM 42 being in a deformed state, such as by being compressed between the heat spreader 36 and the semiconductor dies 18, 20.

In an example described in more detail below, the first and second specified conditions can include different temperatures corresponding to different softening or melting temperatures for the first composition of the first TIM 40 and the second composition of the second TIM 42. For example, the first TIM 40 can have a lower melting or softening temperature than the second TIM 42 (or vice versa) so that if the TIMs 40, 42 are heated to a temperature that is higher than the melting temperature or softening temperature of the first TIM 40, then the first TIM 40 will soften and be able to be compressed between the heat spreader 36 and the first semiconductor die 18 (either because of the weight of the heat spreader 36 or because of additional compression pressure being applied onto the package 12) until the heat spreader 36 can also come into contact with the second TIM 42 to ensure good thermal contact between the heat spreader 36 and both TIMs 40, 42. In another example, described in more detail below, the first and second specified conditions can include different compressibility of the first material that forms the first TIM 40 compared to the compressibility of the second material that forms the second TIM 42. As used herein, the term “softening temperature” refers to the temperature at which a material begins to soften (e.g., become more compressible) but not necessarily liquefy. As used herein, the term “melting temperature” refers to the temperature at which a material begins to transition from a solid to a liquid. In general, for most materials, the softening temperature is lower than the melting temperature, e.g., such that at a certain temperature that is at or above the softening temperature but below the melting temperature, the material may begin to be deformable but will not necessarily begin to transition into a liquid. But that is not necessarily true for all TIMs that may be useful as the TIMs 40 and 42 in the devices of the present disclosure.

As is described in more detail below, the different compositions of the first and second TIMs 40, 42 can allow the TIMs 40, 42 and the heat spreader 36 to accommodate situations where the first semiconductor die 18 and the second semiconductor die 20 have different heights DH₁ and DH₂.

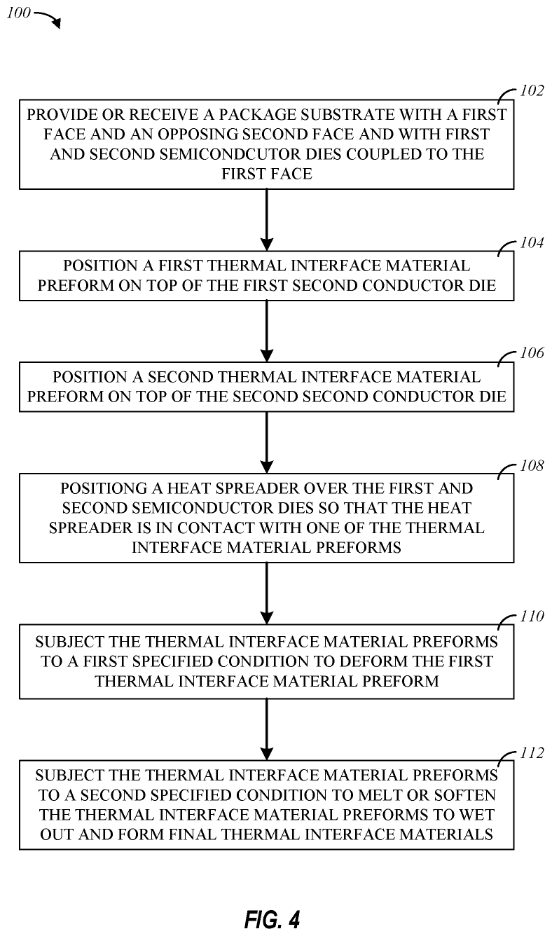

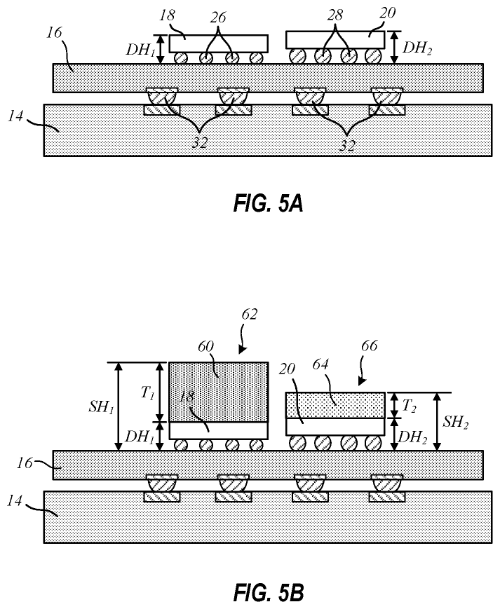

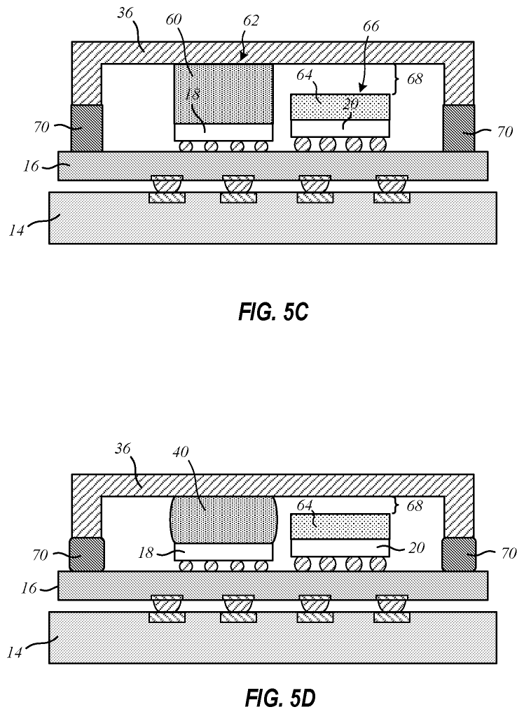

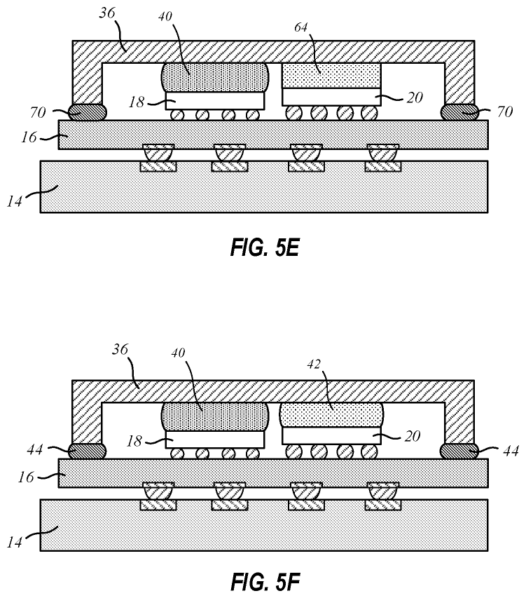

FIG. 4 is a flow diagram of an example method 100 of fabricating an electronic device such as the electronic device 10 shown in FIG. 1. FIGS. 5A-5F show a cross-sectional side view of the electronic device 10 as it is being fabricated by the example method 100 of FIG. 4. In an example, the method 100 includes, at step 102, providing or receiving a package substrate having a first face and an opposing second face (such as the substrate 16 with the first face 22 and the second face 24) with first and second semiconductor dies coupled to the first face (such as the semiconductor dies 18, 20 coupled to the first face 22 of the substrate 16). FIG. 5A shows an example of the package substrate 16 after step 102. As described above, in an example, the first semiconductor die 18 is coupled to the substrate 16 by one or more first solder joints 26 and the second semiconductor die 20 is coupled to the substrate 16 by one or more second solder joints 28. As is also described above, in an example, the first semiconductor die 18 has a first die height DH₁ that is different from a second die height DH₂ of the second semiconductor die 20, which can make it difficult to ensure a good thermal connection between both semiconductor dies 18, 20 and a heat spreader. In the example shown in FIG. 5A, the first die height DH₁ of the first semiconductor die 18 is shorter than the second die height DH₂ of the second semiconductor die 20. However, those having skill in the art will appreciate that this could be reversed, i.e., with the first semiconductor die 18 having a taller die height DH₁ than the die height DH₂ of the second semiconductor die 20. In an example, the package substrate 16 that is provided in step 102 can also be mounted to a circuit board 14, such as via solder joints 32, as shown in FIG. 5A.

Next, the method 100 can include, at step 104, positioning a first thermal interface material preform 60 (also referred to as “the first TIM preform 60”) on top of the first semiconductor die 18 to form a first die and preform stack 62 (also referred to as “the first die/preform stack 62”). The first TIM preform 60 is made from a first thermal interface material composition (also referred to as “the first composition”). The method 100 can also include, at step 106, positioning a second thermal interface material preform 64 on top of the second semiconductor die 20 to form a second die and preform stack 66 (also referred to as “the second die/preform stack 66”). The second thermal interface material preform 64 is made from a second thermal interface material composition (also referred to as “the second composition”). FIG. 5B shows the apparatus after the steps of positioning the first thermal interface material preform 60 to form the first die/preform stack 62 (step 104) and positioning the second thermal interface material preform 64 to form the second die/preform stack 66 (step 106).

In order to accommodate the different die heights DH₁ and DH₂, the two thermal interface material preforms 60, 64 can have different thicknesses so that the total combined height of the first die/preform stack 62 will be different from the total combined height of the second die/preform stack 66. For example, the first thermal interface material preform 60 can have a first thickness T₁, which results in a first total stack height SH₁ that is equal to the sum of the first die height DH₁ of the first semiconductor die 18 and the first thickness T₁ of the first thermal interface material preform 60 (i.e., SH₁=DH₁+Similarly, the second thermal interface material preform 64 can have a second thickness T₂, which results in a second total stack height SH₂ that is equal to the sum of the second die height DH₂ of the second semiconductor die 20 and the second thickness T₂ of the second thermal interface material preform 64 (i.e., SH₂=DH₂+T₂). In the example shown in FIG. the first thermal interface material preform 60 is thicker than the second thermal interface material preform 64 (i.e., T₁>T₂) so that the first stack height SH₁ is taller than the second stack height SH₂ (i.e., SH₁>SH₂). However, those having skill in the art will appreciate that this arrangement could be reversed and the second thermal interface material preform 64 could be thicker than the first thermal interface material preform 60 (i.e., with T₂>T₁) or the second stack height SH₂ could be taller than the first stack height SH₁ (i.e., with SH₂>SH₁), or both. Also, in the example shown in FIG. 5B, the thicker thermal interface material preform 60, 64, e.g., the first thermal interface material preform 60 in FIG. 5B, was placed on the semiconductor die 18, 20 with the lower die height (i.e., the first semiconductor die 18 with the smaller die height DH₁ in the example shown in FIG. 5B). However, the method 100 is not limited to this arrangement. Rather, the thicker thermal interface material preform 60 could be positioned on the semiconductor die 18, 20 that has the taller die height (i.e., the second semiconductor die 20 with the larger die height DH₂ in the example shown in FIG. So long as the stack height of one of the die/preform stacks is larger than the other stack or stacks, so that when a heat spreader is placed on top of the thermal interface material preforms 60, 64 (described in more detail below) the heat spreader will come into contact with one of the die/preform stacks 62, 66 before coming into contact with the other die/preform stack.

After the TIM preforms 60, 64 are positioned to form the die/preform stacks 62, 66 (steps 104 and 106), the method 100 can include, at step 108, positioning a heat spreader (such as the heat spreader 36) over the semiconductor dies 18, 20 so that the heat spreader 36 is in contact with one of the TIM preforms 60, 64. FIG. 5C shows an example of the apparatus after positioning the heat spreader 36 (step 108). Specifically, the heat spreader 36 is placed on top of the die/preform stacks 62, 66 so that the heat spreader 36 is in contact with the outer surface of the TIM preform 60, 64 that is in the die/preform stack 62, 66 with the tallest total stack height SH₁ or SH₂ (e.g., the first TIM preform 60 in the first die/preform stack 62 in the example shown in FIG. 5C). Because the different die/preform stacks 62, 66 have different stack heights SH₁ and SH₂, the die/preform stack or stacks with shorter stack heights (e.g., the second die/preform stack 66 with the shorter stack height SH₂ in the example shown in FIG. 5C) will be spaced below the heat spreader 36 and a gap 68 will form between the heat spreader 36 and the outer surface of the TIM preform 60, 64 having the shorter die/preform stack 66. As will be described in more detail below, the material of the taller TIM preform 60, 64 (e.g., the first TIM preform 60 in the example shown in FIG. 5C) will be deformed and shortened so that eventually the heat spreader 36 will also come into contact with the other TIM preform 64 as well. In an example, the step of positioning the heat spreader 36 (step 108) can include placing a heat spreader adhesive material 70 between the heat spreader 36 and the structure to which the heat spreader 36 is to be adhered (such as the package substrate 16 as shown in FIG. 5C). The adhesive material 70 will eventually be cured to form the final adhesive 44.

The material composition of the TIM preform 60, 64 that is part of the taller die/preform stack 62, 66 (e.g., the first TIM preform 60 in the first die/preform stack 62 in the example shown in FIG. 5C) is more easily deformable when the TIM preforms 60, 64 are subjected to one or more first specified conditions. The more easily deformable material composition allows the TIM preform 60, 64 of the taller die/preform stack 62, 66 to be deformed in a way that allows the heat spreader 36 to move downward and come into contact with the TIM preform 60, 64 of the shorter die/preform stack 62, 66 (e.g., the second TIM preform 64 in the second die/preform stack 66 in the example configuration shown in FIG. 5C) to ensure good thermal contact between the heat spreader 36 and both TIM preforms 60, 64 (and eventually to the TIMs 40, 42 that will be formed from the material of the TIM preforms 60, 64). Therefore, in an example, after positioning the heat spreader 36 onto the die/preform stacks 62, 66 (step 108), the method 100 can include, at step 110, subjecting the TIM preforms 60, 64 to a first specified condition or conditions that causes a first of the TIM preforms 60, 64, e.g., to cause the TIM preform 60, 64 of the taller die/preform stack 62, 66 to become more easily deformable. But the first specified condition or conditions do not cause the other TIM preform or preforms, e.g., the TIM preform 60, 64 of the shorter die/preform stack 66, to become deformable. Thus, when the TIM preforms 60, 64 are subjected to the first specified condition or conditions, the TIM preform of the taller die/preform stack 62, 66 (e.g., the first TIM preform 60) can deform and slump downward. FIG. 5D shows an intermediate stage after starting to subject the TIM preforms 60, 64 to the first specified condition or conditions (step 110), wherein the first TIM preform 60 has started to deform and the heat spreader 36 has begun to move downward. As can be seen in FIG. 5D, the gap 68 between the outer surface of the second TIM preform 64 and the heat spreader 36 has gotten smaller between FIG. 5C and FIG. 5D. As can also be seen in FIG. the adhesive material 70 has been compressed slightly between the heat spreader 36 and the package substrate 16. As the TIM preforms 60, 64 are continued to be subjected to the first specified condition or conditions, the first TIM preform 60 can continue to be deformed and the heat spreader 36 can continue to move downward until the heat spreader 36 comes into contact with the second TIM preform 64, as shown in FIG. 5E. Because the second TIM preform 64 does not become deformable when subjected to the first specified condition or conditions, e.g., the second TIM preform 64 remains solid, the heat spreader 36 does not move downward any further and is held up by the second TIM preform 64.

In a basic example, the first specified condition or conditions can be temperature based, with the first composition that forms the first TIM preform 60 having a first melting or softening temperature that is different from a second melting or softening temperature of the second composition that forms the second TIM preform 64. In an example, the first melting or softening temperature is lower than the second melting or softening temperature, for example at least about 5° C. lower than the second melting or softening temperature, such as at least about 6° C. lower, at least about 7° C. lower, at least about 7.5° C. lower, at least about 8° C. lower, at least about 9° C. lower, at least about 10° C. lower, at least about 12.5° C. lower, at least about 15° C. lower, at least about 20° C. lower, or more. In another example, the second melting or softening temperature is lower than the first melting or softening temperature, for example at least about 5° C. lower than the first melting or softening temperature, such as at least about 6° C. lower, at least about 7° C. lower, at least about 7.5° C. lower, at least about 8° C. lower, at least about 9° C. lower, at least about 10° C. lower, at least about 12.5° C. lower, at least about 15° C. lower, at least about 20° C. lower, or more.

In the example configuration shown in FIG. 5C, i.e., wherein the first die/preform stack 62 is taller than the second die/preform stack 66, then the first composition for the first TIM preform 60 can be selected with a lower melting temperature than the second composition for the second TIM preform 64, the step of subjecting the TIM preforms 60, 64 to the first specified condition (step 110) comprises heating the TIM preforms 60, 64 to a temperature that is higher than the first melting or softening temperature of the first TIM preform 60 but lower than the second melting or softening temperature of the second TIM preform 64. This heating causes the first TIM preform 60 to soften and/or melt such that the first TIM preform 60 can be compressed downward. For example, the weight of the heat spreader 36 can push onto the softened or melted TIM preform 60, which can cause the first TIM preform 60 to slump or otherwise compress (as shown in FIGS. 5D and 5E). The slumping and/or compression of the first TIM preform 60 allows the heat spreader 36 to move downward relative to the semiconductor dies 18, 20 until eventually the heat spreader 36 comes into contact with the second TIM preform 64, which has remained solid because the temperature of the first specified condition or conditions is still below the second melting or softening temperature of the second TIM preform 64. The still-solid second TIM preform 64 acts to stop the downward motion of the heat spreader 36 relative to the TIM preforms 60, 64, as shown in FIG. 5E. In examples wherein the first specified condition or conditions comprises heating the TIM preforms 60, 64 to a temperature above the first melting or softening temperature of the first composition of the first TIM preform 60, the first TIM preform 60 softens or melts such that the material of the first TIM preform 60 wets out onto the outer surface of the first semiconductor die 18 and onto the bottom surface of the heat spreader 36 to form what becomes the final first thermal interface material 40, as shown in FIG. 5E.

In another example, the first specified condition or conditions can be based on the compressibility of the first and second compositions that form the first TIM preform 60 and the second TIM preform 64, respectively. As used herein, the term “compressibility” refers to the ability of a material to change in size in at least one direction in response to a pressure exerted onto the material (with the change in size usually occurring in the same direction that the pressure is being exerted). If a material is considered to be “more compressible,” then it will have a greater change in size in response to the exerted pressure then another material that is “less compressible.”

In the example configuration shown in FIG. 5C, i.e., wherein the first die/preform stack 62 is taller than the second die/preform stack 66, then the first composition for the first TIM preform 60 can be more compressible than the second composition for the second TIM preform 64, i.e., the first composition of the first TIM preform 60 can have a first compressibility that is higher than a second compressibility of the second composition of the second TIM preform 64 so that the first TIM preform 60 will deform more than the second TIM preform 64 under the same applied pressure. In such a configuration, the step of subjecting the TIM preforms 60, 64 to the first specified condition (step 110) comprises applying a compression pressure to the TIM preforms 60, 64 that is sufficient to compress the first TIM preform 60 but that is not large enough to compress the second TIM preform 64. In an example, applying the compression pressure comprises forcing the heat spreader 36 downward toward the TIM preforms 60, 64 so that the heat spreader 36 compresses the first TIM preform 60 into the first semiconductor die 18 and compresses the second TIM preform 64 into the second semiconductor die 20. The compression pressure causes the first TIM preform 60 to be deformed downward (e.g., as shown in FIG. 5D) such that the heat spreader 36 is able to move downward relative to the semiconductor dies 18, 20 until eventually the heat spreader 36 comes into contact with the second TIM preform 64, as shown in FIG. 5E. Because the exerted compression pressure is selected so that it does not compress the second composition of the second TIM preform 64, the uncompressed second TIM preform 64 acts to stop the downward motion of the heat spreader 36 relative to the TIM preforms 60, 64.

In an example, the step of subjecting the TIM preforms 60, 64 to the first specified condition or conditions (step 110) can also include deforming the adhesive material between the heat spreader 36 and the structure to which the heat spreader 36 is to be adhered (i.e., the package substrate 16 in the example shown in the Figures), as shown in FIGS. 5D and 5E.

After subjecting the TIM preforms 60, 64 to the first specified condition or conditions (step 110), the method 100 can include, at step 112, subjecting the TIM preforms 64 to a second specified condition or conditions so that both TIM preforms 60, 64 have sufficient thermal contact between their corresponding semiconductor die 18, 20 and the heat spreader 36. In an example, subjecting the TIM preforms 60, 64 to the second specified condition or conditions includes heating the TIM preforms 60, 64 to a temperature that is above both the first and second melting or softening temperatures of the first and second TIM preforms 60, 64, e.g., so that the material of the first TIM preform 60 wets out onto the outer surface of the first semiconductor die 18 and onto the bottom surface of the heat spreader 36 to form what becomes the final first thermal interface material 40 and so that the material of the second TIM preform 64 wets out onto the outer surface of the second semiconductor die and onto the bottom surface of the heat spreader 36 to form what becomes the final second thermal interface material 42, as shown in FIG. 5F. In an example, heating the TIM preforms 64 above their melting or softening temperatures to wet out and form the final thermal interface materials 40, 42 can also act to cure the adhesive material 70 to form the final adhesive 44 that adheres the heat spreader 36 to the structure to which it is adhered (e.g., the package substrate 16 as shown in FIG. 5F).

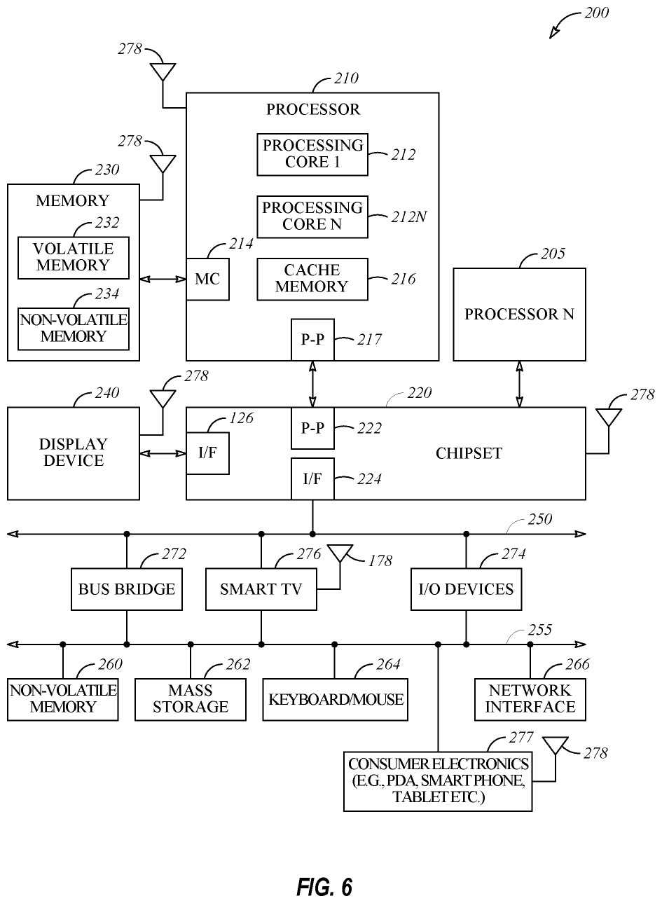

FIG. 6 illustrates a system level diagram, depicting an example of an electronic device (e.g., system) that may include the multi-composition thermal interface material configurations and/or methods described above. In one embodiment, the system 200 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance, or any other type of computing device. In some embodiments, system 200 includes a system on a chip (SOC) system.

In one embodiment, processor 210 has one or more processor cores 212 and 212N, where 212N represents the Nth processor core inside processor 210 where N is a positive integer. In one embodiment, system 200 includes multiple processors including 210 and 205, where processor 205 has logic similar or identical to the logic of processor 210. In some embodiments, processing core 212 includes, but is not limited to, pre-fetch logic to fetch instructions, decode logic to decode the instructions, execution logic to execute instructions and the like. In some embodiments, processor 210 has a cache memory 216 to cache instructions and/or data for system 200. Cache memory 216 may be organized into a hierarchal structure including one or more levels of cache memory.

In some embodiments, processor 210 includes a memory controller 214, which is operable to perform functions that enable the processor 210 to access and communicate with memory 230 that includes a volatile memory 232 and/or a non-volatile memory 234. In some embodiments, processor 210 is coupled with memory 230 and chipset 220. Processor 210 may also be coupled to a wireless antenna 278 to communicate with any device configured to transmit and/or receive wireless signals. In one embodiment, an interface for wireless antenna 278 operates in accordance with, but is not limited to, the IEEE 802.11 standard and its related family, Home Plug AV (HPAV), Ultra-Wide Band (UWB), Bluetooth, WiMax, or any form of wireless communication protocol.

In some embodiments, volatile memory 232 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 234 includes, but is not limited to, flash memory, phase change memory (PCM), read-only memory (ROM), electrically erasable programmable read-only memory (EEPROM), or any other type of non-volatile memory device.

Memory 230 stores information and instructions to be executed by processor 210. In one embodiment, memory 230 may also stores temporary variables or other intermediate information while processor 210 is executing instructions. In the illustrated embodiment, chipset 220 connects with processor 210 via Point-to-Point (PtP or P-P) interfaces 217 and 222. Chipset 220 enables processor 210 to connect to other elements in system 200. In some embodiments of the example system, interfaces 217 and 222 operate in accordance with a PtP communication protocol such as the Intel® QuickPath Interconnect (QPI) or the like. In other embodiments, a different interconnect may be used.

In some embodiments, chipset 220 is operable to communicate with processor 210, 205N, display device 240, and other devices, including a bus bridge 272, a smart TV 276, I/O devices 274, nonvolatile memory 260, a storage medium 262 (such as one or more mass storage devices), a keyboard/mouse 264, a network interface 266, and various forms of consumer electronics 277 (such as a PDA, smart phone, tablet etc.), etc. In one embodiment, chipset 220 couples with these devices through an interface 224. Chipset 220 may also be coupled to a wireless antenna 278 to communicate with any device configured to transmit and/or receive wireless signals. In one example, any combination of components in a chipset may be separated by a continuous flexible shield as described in the present disclosure.

Chipset 220 connects to display device 240 via interface 226. Display 240 may be, for example, a liquid crystal display (LCD), a light emitting diode (LED) array, an organic light emitting diode (OLED) array, or any other form of visual display device. In some embodiments of the example system, processor 210 and chipset 220 are merged into a single SOC. In addition, chipset 220 connects to one or more buses 250 and 255 that interconnect various system elements, such as I/O devices 274, nonvolatile memory 260, storage medium 262, a keyboard/mouse 264, and network interface 266. Buses 250 and 255 may be interconnected together via a bus bridge 272.

In one embodiment, mass storage device 262 includes, but is not limited to, a solid state drive, a hard disk drive, a universal serial bus flash memory drive, or any other form of computer data storage medium. In one embodiment, network interface 266 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra-Wide Band (UWB), Bluetooth, WiMax, or any form of wireless communication protocol.

While the modules shown in FIG. 6 are depicted as separate blocks within the system 200, the functions performed by some of these blocks may be integrated within a single semiconductor circuit or may be implemented using two or more separate integrated circuits. For example, although cache memory 216 is depicted as a separate block within processor 210, cache memory 216 (or selected aspects of 216) can be incorporated into processor core 212.

To better illustrate the methods and apparatuses disclosed herein, a non-limiting list of exemplary embodiments are provided here:
EMBODIMENT 1 can include subject matter (such as an apparatus, a device, a method, or one or more means for performing acts), such as can include a die package comprising a substrate comprising a first face and an opposing second face, a first semiconductor die coupled to the first face of the substrate, a second semiconductor die coupled to the first face of the substrate, and a heat spreader, wherein the first semiconductor die is thermally connected to the heat spreader by a first thermal interface material and the second semiconductor die is thermally connected to the heat spreader by a second thermal interface material, wherein the first thermal interface material comprises a first composition and the second thermal interface material comprises a second composition, wherein the first composition has a lower elastic modulus than the second composition under a first specified condition or conditions.
EMBODIMENT 2 can include, or can optionally be combined with the subject matter of EMBODIMENT 1, to optionally include a first softening temperature of the first composition being lower than a second softening temperature of the second composition.
EMBODIMENT 3 can include, or can optionally be combined with the subject matter of EMBODIMENT 2, to optionally include the first softening temperature being at least about 5° C. lower than the second softening temperature.
EMBODIMENT 4 can include, or can optionally be combined with the subject matter of EMBODIMENT 2, to optionally include the first softening temperature being at least about 10° C. lower than the second softening temperature.
EMBODIMENT 5 can include, or can optionally be combined with the subject matter of one or any combination of EMBODIMENTS 1-4, to optionally include a first melting temperature of the first composition being lower than a second melting temperature of the second composition.
EMBODIMENT 6 can include, or can optionally be combined with the subject matter of EMBODIMENT 5, to optionally include the first melting temperature being at least about 5° C. lower than the second melting temperature.
EMBODIMENT 7 can include, or can optionally be combined with the subject matter of EMBODIMENT 5, to optionally include the first melting temperature being at least about 10° C. lower than the second melting temperature.
EMBODIMENT 8 can include, or can optionally be combined with the subject matter of one or any combination of EMBODIMENTS 1-7, to optionally include a first compressibility of the first composition of the first thermal interface material at the first specified condition or conditions being higher than a second compressibility of the second composition of the second thermal interface material.
EMBODIMENT 9 can include, or can optionally be combined with the subject matter of one or any combination of EMBODIMENTS 1-8, to optionally include a first height of the first semiconductor die relative to the first face of the substrate being different from a second height of the second semiconductor die relative to the first face of the substrate.
EMBODIMENT 10 can include, or can optionally be combined with the subject matter of one or any combination of EMBODIMENTS 1-9, to optionally include the first thermal interface material comprising a first solder composition.
EMBODIMENT 11 can include, or can optionally be combined with the subject matter of one or any combination of EMBODIMENTS 1-10, to optionally include the second thermal interface material comprising as second solder composition.
EMBODIMENT 12 can include, or can optionally be combined with the subject matter of EMBODIMENT 7, to optionally include the second solder composition being different from the first solder composition.
EMBODIMENT 13 can include, or can optionally be combined with the subject matter of one or any combination of EMBODIMENTS 1-12, to optionally include the first and second semiconductor dies each being one of a memory device, a computer processing unit (CPU), a graphics processing unit (GPU), or a processor.
EMBODIMENT 14 can include, or can optionally be combined with the subject matter of one or any combination of EMBODIMENTS 1-13, to include subject matter (such as an apparatus, a device, a method, or one or more means for performing acts), such as can include an electronic device comprising a circuit board; and a die package coupled to the circuit board with one or more solder joints, wherein the die package comprises a package substrate comprising a first face and an opposing second face, a first semiconductor die and a second semiconductor die coupled to the first face of the substrate, and a heat spreader, wherein the first semiconductor die is thermally connected to the heat spreader by a first thermal interface material and the second semiconductor die is thermally connected to the heat spreader by a second thermal interface material, wherein the first thermal interface material comprises a first composition and the second thermal interface material comprises a second composition, wherein the first composition is deformable under a first specified condition or conditions, and wherein the second composition is not deformable under the first specified condition or conditions.
EMBODIMENT 15 can include, or can optionally be combined with the subject matter of EMBODIMENT 14, to optionally include a first softening temperature of the first composition being lower than a second softening temperature of the second composition.
EMBODIMENT 16 can include, or can optionally be combined with the subject matter of EMBODIMENT 15, to optionally include the first softening temperature being at least about 5° C. lower than the second softening temperature.
EMBODIMENT 17 can include, or can optionally be combined with the subject matter of EMBODIMENT 15, to optionally include the first softening temperature being at least about 10° C. lower than the second softening temperature.
EMBODIMENT 18 can include, or can optionally be combined with the subject matter of one or any combination of EMBODIMENTS 14-16, to optionally include a first melting temperature of the first composition being lower than a second melting temperature of the second composition.
EMBODIMENT 19 can include, or can optionally be combined with the subject matter of EMBODIMENT 18, to optionally include the first melting temperature being at least about 5° C. lower than the second melting temperature.
EMBODIMENT 20 can include, or can optionally be combined with the subject matter of EMBODIMENT 18, to optionally include the first melting temperature being at least about 10° C. lower than the second melting temperature.
EMBODIMENT 21 can include, or can optionally be combined with the subject matter of ne or any combination of EMBODIMENTS 14-20, to optionally include a first compressibility of the first composition of the first thermal interface material at the first specified condition or conditions being higher than a second compressibility of the second composition of the second thermal interface material.
EMBODIMENT 22 can include, or can optionally be combined with the subject matter of one or any combination of EMBODIMENTS 14-21, to optionally include a first height of the first semiconductor die relative to the first face of the substrate being different from a second height of the second semiconductor die relative to the first face of the substrate.
EMBODIMENT 23 can include, or can optionally be combined with the subject matter of one or any combination of EMBODIMENTS 14-22, to optionally include the first composition of the first thermal interface material comprising a first solder composition.
EMBODIMENT 24 can include, or can optionally be combined with the subject matter of one or any combination of EMBODIMENTS 14-23, to optionally include the second composition of the second thermal interface material comprising a second solder composition.
EMBODIMENT 25 can include, or can optionally be combined with the subject matter of EMBODIMENT 24, to optionally include the second solder composition being different from the first solder composition.
EMBODIMENT 26 can include, or can optionally be combined with the subject matter of one or any combination of EMBODIMENTS 14-25, to optionally include the circuit board comprising a mother board.
EMBODIMENT 27 can include, or can optionally be combined with the subject matter of one or any combination of EMBODIMENTS 14-26, to optionally include an antenna coupled to the circuit board.
EMBODIMENT 28 can include, or can optionally be combined with the subject matter of one or any combination of EMBODIMENTS 14-27, to optionally include the first and second semiconductor dies each being one of a memory device, a computer processing unit (CPU), a graphics processing unit (GPU), or a processor.
EMBODIMENT 29 can include, or can optionally be combined with the subject matter of one or any combination of EMBODIMENTS 1-28, to include subject matter (such as an apparatus, a device, a method, or one or more means for performing acts), such as can include a method of manufacturing a die package, the method comprising providing or receiving a package substrate having a first face and an opposing second face with a first semiconductor die and a second semiconductor die coupled to the first face, positioning a first thermal interface material preform on the first semiconductor die, wherein the first thermal interface preform comprises a first composition, positioning a second thermal interface material preform on the second semiconductor die, wherein the second thermal interface preform comprises a second composition, wherein the first composition is deformable under a first specified condition or conditions and wherein the second composition is not deformable under the first specified condition or conditions, positioning a heat spreader over the first and second semiconductor dies so that the heat spreader is in contact with the first thermal interface material preform, and subjecting the first thermal interface material preform and the second thermal interface material preform to a first specified condition or conditions to deform the first thermal interface material preform such that the heat spreader comes into contact with the second thermal interface material preform.
EMBODIMENT 30 can include, or can optionally be combined with the subject matter of EMBODIMENT 29, to optionally include a first height of the first semiconductor die relative to the first face of the substrate being different from a second height of the second semiconductor die relative to the first face of the substrate
EMBODIMENT 31 can include, or can optionally be combined with the subject matter of either one or a combination of EMBODIMENT 29 and EMBODIMENT 30, to optionally include the first thermal interface material preform having a first thickness and the second thermal interface material preform having a second thickness that is different from the first thickness.
EMBODIMENT 32 can include, or can optionally be combined with the subject matter of one or any combination of EMBODIMENTS 29-31, to optionally include a first softening temperature of the first composition being lower than a second softening temperature of the second composition.
EMBODIMENT 33 can include, or can optionally be combined with the subject matter of EMBODIMENT 32, to optionally include the subjecting of the first thermal interface material preform and the second thermal interface material preform to the first specified condition comprising heating the first thermal interface material preform and the second thermal interface material preform to a temperature that is higher than the first softening temperature and lower than the second softening temperature.
EMBODIMENT 34 can include, or can optionally be combined with the subject matter of either one or a combination of EMBODIMENT 32 and EMBODIMENT 33, to optionally include the second softening temperature being at least about 5° C. higher than the first softening temperature.
EMBODIMENT 35 can include, or can optionally be combined with the subject matter of one or a combination of EMBODIMENT 32 and EMBODIMENT 33, to optionally include the first softening temperature being at least about 10° C. lower than the second softening temperature.
EMBODIMENT 36 can include, or can optionally be combined with the subject matter of one or any combination of EMBODIMENTS 29-35, to optionally include a first melting temperature of the first composition being lower than a second melting temperature of the second composition.
EMBODIMENT 37 can include, or can optionally be combined with the subject matter of EMBODIMENT 36, to optionally include the first melting temperature being at least about 5° C. lower than the second melting temperature.
EMBODIMENT 38 can include, or can optionally be combined with the subject matter of EMBODIMENT 36, to optionally include the first melting temperature being at least about 10° C. lower than the second melting temperature.
EMBODIMENT 39 can include, or can optionally be combined with the subject matter of one or any combination of EMBODIMENTS 29-38, to optionally include the first composition having a first compressibility and the second composition having a second compressibility that is lower than the first compressibility at the first specified condition or conditions.
EMBODIMENT 40 can include, or can optionally be combined with the subject matter of EMBODIMENT 39, to optionally include the subjecting of the first thermal interface material preform and the second thermal interface material preform to the first specified condition or conditions comprises applying a compression pressure on the first thermal interface material preform or the second thermal interface material preform, or both, wherein the compression pressure is high enough to compress the first thermal interface material preform but not to compress the second thermal interface material preform.
EMBODIMENT 41 can include, or can optionally be combined with the subject matter of one or any combination of EMBODIMENTS 29-40, to optionally include the first composition of the first thermal interface material preform comprising a first solder composition.
EMBODIMENT 42 can include, or can optionally be combined with the subject matter of one or any combination of EMBODIMENTS 29-41, to optionally include the second composition of the second thermal interface material perform comprising a second solder composition.
EMBODIMENT 43 can include, or can optionally be combined with the subject matter of EMBODIMENT 42, to optionally include the second solder composition being different from the first solder composition.
EMBODIMENT 44 can include, or can optionally be combined with the subject matter of one or any combination of EMBODIMENTS 29-43, to optionally include adhering the heat spreader to the package substrate.
EMBODIMENT 45 can include, or can optionally be combined with the subject matter of one or any combination of EMBODIMENTS 29-44, to optionally include coupling the second face of the package substrate to a circuit board with one or more interconnect solder joints.
EMBODIMENT 46 can include or can optionally be combined with the subject matter of EMBODIMENT 45 to optionally include the circuit board comprising a mother board.
EMBODIMENT 47 can include or can optionally be combined with the subject matter of either one or a combination of EMBODIMENT 45 and EMBODIMENT 46, to optionally include coupling an antenna to the circuit board.
EMBODIMENT 48 can include, or can optionally be combined with the subject matter of one or any combination of EMBODIMENTS 29-47, to optionally include the first and second semiconductor dies each being one of a memory device, a computer processing unit (CPU), a graphics processing unit (GPU), or a processor.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. A die package comprising:
a substrate comprising a first face and an opposing second face;
a first semiconductor die coupled to the first face of the substrate;
a second semiconductor die coupled to the first face of the substrate; and
a heat spreader, wherein the first semiconductor die is thermally connected to the heat spreader by a first thermal interface material and the second semiconductor die is thermally connected to the heat spreader by a second thermal interface material;
wherein the first thermal interface material comprises a first composition and the second thermal interface material comprises a second composition different than the first composition, wherein a first softening temperature of the first composition is lower than a second softening temperature of the second composition.

2. The die package of claim 1, wherein the first composition has a lower elastic modulus than the second composition under a first specified condition or conditions.

3. The die package of claim 1, wherein the first softening temperature is at least about 5° C. lower than the second softening temperature.

4. The die package of claim 1, wherein a first compressibility of the first composition of the first thermal interface material at the first specified condition or conditions is higher than a second compressibility of the second composition of the second thermal interface material.

5. The die package of claim 1, wherein a first height of the first semiconductor die relative to the first face of the substrate is different from a second height of the second semiconductor die relative to the first face of the substrate.

6. The die package of claim 1, wherein the first thermal interface material comprises a first solder composition and the second thermal interface material comprises a second solder composition that is different from the first solder composition.

7. The die package of claim 1, wherein the first and second semiconductor dies are each one of a memory device, a computer processing unit (CPU), a graphics processing unit (GPU), or a processor.

8. An electronic device comprising:
a circuit board; and
a die package coupled to the circuit board with one or more solder joints, wherein the die package comprises:
a package substrate comprising a first face and an opposing second face;
a first semiconductor die and a second semiconductor die coupled to the first face of the substrate; and
a heat spreader, wherein the first semiconductor die is thermally connected to the heat spreader by a first thermal interface material and the second semiconductor die is thermally connected to the heat spreader by a second thermal interface material;
wherein the first thermal interface material comprises a first composition and the second thermal interface material comprises a second composition different than the first composition, wherein a first softening temperature of the first composition is lower than a second softening temperature of the second composition.

9. The electronic device of claim 8, wherein the first composition has a lower elastic modulus than the second composition under a first specified condition or conditions.

10. The electronic device of claim 8, wherein the first softening temperature is at least about 5° C. lower than the second softening temperature.

11. The electronic device of claim 8, wherein the circuit board comprises a mother board.

12. The electronic device of claim 8, further comprising an antenna coupled to the circuit board.

13. The electronic device of claim 8, wherein further comprising an antenna coupled to the circuit board.

14. A method of manufacturing a die package, the method comprising:
providing or receiving a package substrate having a first face and an opposing second face with a first semiconductor die and a second semiconductor die coupled to the first face;
positioning a first thermal interface material preform on the first semiconductor die, wherein the first thermal interface preform comprises a first composition;
positioning a second thermal interface material preform on the second semiconductor die, wherein the second thermal interface preform comprises a second composition different than the first composition;
wherein the first composition is deformable under a first specified condition or conditions and wherein the second composition is not deformable under the first specified condition or conditions;
positioning a heat spreader over the first and second semiconductor dies so that the heat spreader is in contact with the first thermal interface material preform; and
subjecting the first thermal interface material preform and the second thermal interface material preform to a first specified condition or conditions to deform the first thermal interface material preform such that the heat spreader comes into contact with the second thermal interface material preform.

15. The method of claim 14, wherein the first thermal interface material preform has a first thickness and the second thermal interface material preform has a second thickness that is different from the first thickness.

16. The method of claim 14, wherein a first softening temperature of the first composition is lower than a second softening temperature of the second composition, and wherein subjecting the first thermal interface material preform and the second thermal interface material preform to the first specified condition or conditions comprises heating the first thermal interface material preform and the second thermal interface material preform to a temperature that is higher than the first softening temperature and lower than the second softening temperature.

17. The method of claim 15, wherein the second softening temperature is at least about 5° C. higher than the first softening temperature.

18. The method of claim 14, wherein the first composition has a first compressibility and the second composition has a second compressibility that is lower than the first compressibility, and wherein subjecting the first thermal interface material preform and the second thermal interface material preform to the first specified condition or conditions comprises applying a compression pressure on the first thermal interface material preform or the second thermal interface material preform, or both, wherein the compression pressure is high enough to compress the first thermal interface material preform but not the second thermal interface material preform.

19. The method of claim 14, further comprising adhering the heat spreader to the package substrate.

20. The method of claim 14, further comprising coupling the second face of the package substrate to a circuit board with one or more interconnect solder joints.

21. The method of claim 20, wherein the circuit board comprises a mother board.
